(19) United States
(12) Patent Application Publication
(10) Pub. No.: US 2003/0122590 A1
(43) Pub. Date: Jul. 3, 2003

(54) Low voltage detector

(75) Inventor: Se Eun O, Suwon-Shi (KR)

Correspondence Address: MORGAN LEWIS & BOCKIUS LLP, 1111 PENNSYLVANIA AVENUE NW, WASHINGTON, DC, 20004, US

(73) Assignee: Hynix Semiconductor Inc.

(21) Appl. No.: 10/284,492

(22) Filed: Oct. 31, 2002

(30) Foreign Application Priority Data
Dec. 29, 2001 (KR) 2001-87986

(51) Int. Cl. H03K 5/153

(52) U.S. Cl. 327/77

(57) ABSTRACT

The present invention relates to a low voltage detector. The low voltage detector comprises a first flash memory cell driven by a ground voltage, for maintaining the potential of a first node to a given potential; a second flash memory cell driven by a power supply voltage, for controlling the potential of a second node; and a comparator for comparing the potentials of the first node and the second node. The difference in current between the first over-erased flash memory cell and the second weakly-programmed flash memory cell is sensed instead of using the reference voltage generator. Thus, a low voltage to be sensed can be freely determined by controlling a cell current. Further, according to the present invention, a constant current can be secured without being affected by change in the supply voltage using the over-erased flash memory cell. In addition, as a circuit to which the first and second flash memory cells are connected is symmetrically constructed, the circuit is not affected by change in the temperature or process.

### BACKGROUND OF THE INVENTION

1. Field of the Invention

The invention relates generally to a low voltage detector. More particularly, the present invention relates to a low voltage detector that can change a low voltage detect point without changing a circuit by sensing the difference in current between a first over-erased flash memory cell and a second weakly-programmed flash memory cell to detect a low voltage, that is not affected by change in the operating power using the first over-erased flash memory cell, and that is not affected by change in the temperature or process by symmetrically constructing circuits to which the first and second flash memory cells are connected.

2. Description of the Prior Art

IC circuits or flash memory devices could not properly operate at a low supply voltage Vcc. Thus, a circuit for sensing the low supply voltage and then informing the device of the fact is required.

There is shown a circuit diagram of a conventional low voltage detector in FIG. 1. As shown in FIG. 1, if the power supply voltage Vcc is applied, the voltage is divided by first and second resistors R11 and R12. The divided voltage INa is inputted to one input terminal of a comparator 12. Further, a reference voltage INb generated in a reference voltage generator 11 is inputted to the other input terminal of the comparator 12. The comparator 12 compares the divided voltage INa and the reference voltage INb to output an output signal LVCC depending on the result.

In the above, if the power supply voltage Vcc is increased, the divided voltage INa accordingly increases. Then, the comparator 12 for comparing the divided voltage INa and the reference voltage INb outputs a signal of a LOW state. On the contrary, if the supply voltage Vcc is decreased, the divided voltage INa accordingly decreases. Then, the comparator 12 for comparing the divided voltage INa and the reference voltage INb outputs a signal of a HIGH state. At this time, a low voltage detect points indicates a point where the divided voltage INa becomes lower than the reference voltage INb.

The low voltage detector requires a reference voltage generator for generating the reference voltage without being affected by change in the operation voltage as well as temperature or process, in order to detect the voltage exactly.

However, there are problems that not only it is difficult to construct the reference voltage generator having these characteristics but also the circuit has to be modified again if there is a difference between an actual circuit and a simulation result. Therefore, it is difficult to detect a low voltage exactly.

### SUMMARY OF THE INVENTION

The present invention is contrived to solve the above problems and an object of the present invention is to provide a low voltage detector capable of exactly detecting a low voltage without being affected by change in temperature, process and operating voltage.

In the present invention, the difference in current between the first over-erased flash memory cell and the second weakly-programmed flash memory cell is sensed instead of using the reference voltage generator. Thus, a low voltage to be sensed can be freely determined by controlling a cell current. Further, according to the present invention, a constant current can be secured without being affected by change in the supply voltage using the over-erased flash memory cell. In addition, first and second flash memory cells are symmetrically constructed not to be affected change in the temperature or process.

In order to accomplish the above object, a low voltage detector according to the present invention, is characterized in that it comprises a first flash memory cell driven by a ground voltage, for maintaining the potential of a first node to a given potential; a second flash memory cell driven by a power supply voltage, for controlling the potential of a second node; and a comparator for comparing the potentials of the first node and the second node.

### BRIEF DESCRIPTION OF THE DRAWINGS

The aforementioned aspects and other features of the present invention will be explained in the following description, taken in conjunction with the accompanying drawings, wherein:

FIG. 1 is a circuit diagram of a conventional low voltage detector.

FIG. 2 is a circuit diagram of a low voltage detector according to the present invention.

FIG. 3A and FIG. 3B are graphs showing current and voltage characteristics of the low voltage detector according to the present invention.

FIG. 4 is a graph showing a simulation result of the low voltage detector according to the present invention.

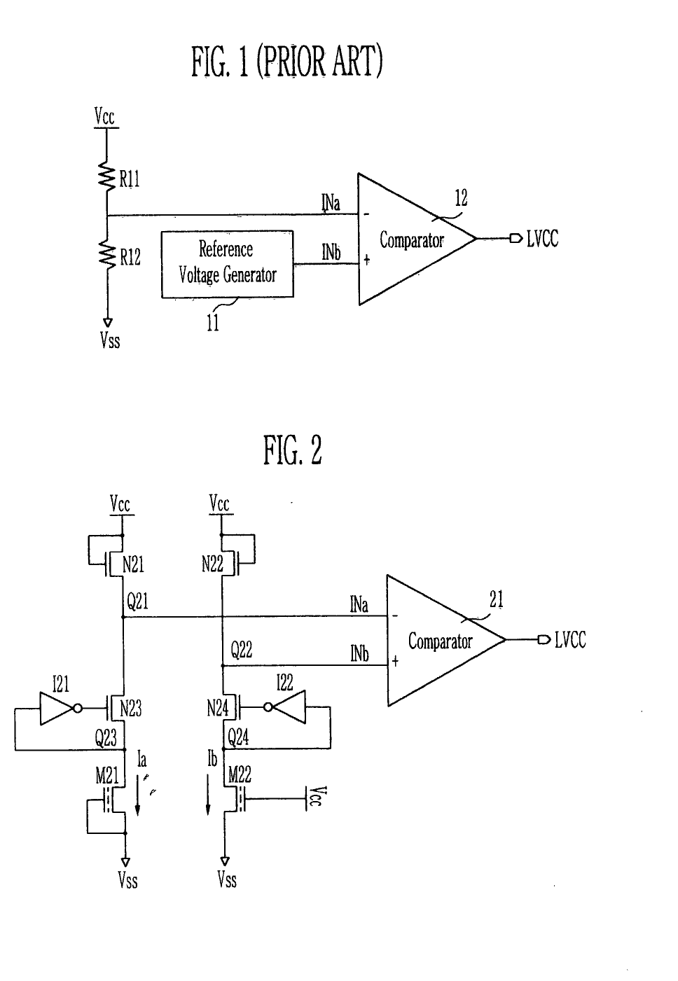

### DETAILED DESCRIPTION OF PREFERRED EMBODIMENTS

The present invention will be described in detail by way of a preferred embodiment with reference to accompanying drawings, in which like reference numerals are used to identify the same or similar parts.

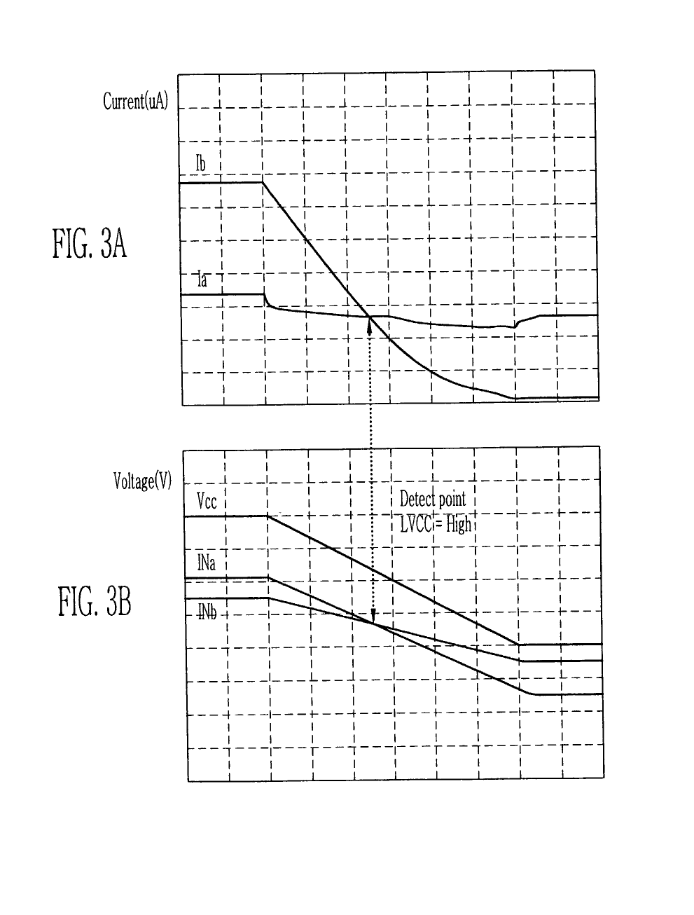

Referring now to FIG. 2, a construction of a low voltage detector according to the present invention will be described. A first NMOS transistor N21, as a first load, is connected between the power supply terminal Vcc and a first node Q21. The gate of the first NMOS transistor N21 is connected to the power supply terminal Vcc for serving as a diode. A third NMOS transistor N23, that is driven by an output signal of a first inverter I21 for inverting the potential of a third node Q23, is connected between the first node Q21 and the third node Q23, that is a drain terminal of the first flash memory cell M21. Also, the first flash memory cell M21 the gate of which is connected to the ground terminal Vss is connected between the third node Q23 and the ground terminal Vss. The first flash memory cell M21 consists of over-erased cells, so that a first current Ia can flow constantly regardless of the supply voltage Vcc. Meanwhile, a second NMOS transistor N22, as a second load, is connected between the power supply terminal Vcc and the second node Q22. The gate of the second NMOS transistor is connected to the power supply terminal Vcc for serving as a diode.

A fourth NMOS transistor N24, that is driven by an output signal of a second inverter I22 for inverting the potential of a fourth node Q24, is connected between the second node Q22 and the fourth node Q24, that is a drain terminal of the second flash memory cell M22. The second flash memory cell M22 the gate terminal of which is applied the supply voltage Vcc is connected between the fourth node Q24 and the ground terminal Vss. At this time, the second flash memory cell M22 consists of weakly-programmed cells. The comparator 21 has an inverting input terminal (−) to which the potential INa of the first node Q21 is inputted and a non-inverting input terminal (+) to which the potential of INb of the second node Q22 is inputted. The comparator 21 compares the potentials INa and INb and then outputs an output signal LVCC depending on the result.

A method of driving the low voltage detector constructed above will be below described.

The supply voltage Vcc is supplied to the first node Q21 via the first NMOS transistor N21 serving as a diode. The first node Q21 has the potential controlled depending a state of the third NMOS transistor N23 and the first flash memory cell M21. At this time, the third NMOS transistor N23 is driven by the output signal of the first inverter I21 for inverting the drain potential of the first flash memory cell M21, that is the potential of the third node Q23. The first flash memory cell M21 is a cell for maintaining an over-erase state, to the gate terminal of which is applied the voltage Vss. As the gate terminal of the first flash memory cell M21 is connected to the ground terminal Vss, the first current Ia through the first flash memory cell M21 is kept constant. Therefore, the potential INa of the first node Q21 is kept constant.

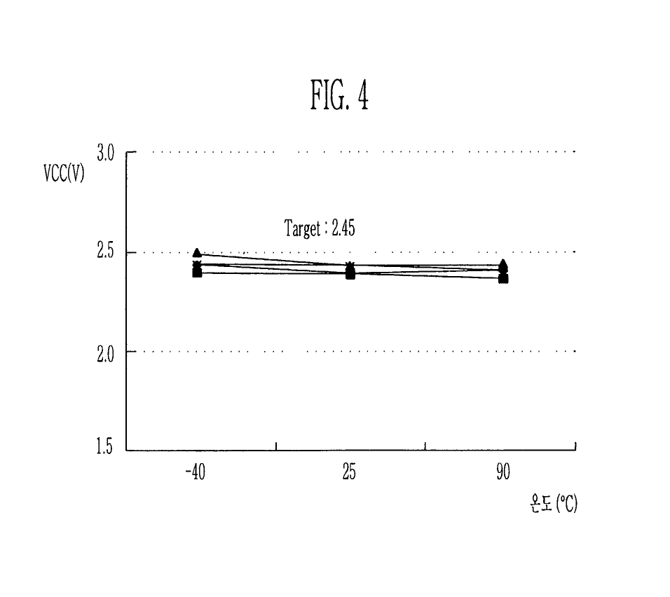

Likewise, the supply voltage Vcc is supplied to second node Q22 via the second NMOS transistor N22 serving as a diode. The second node Q22 has the potential controlled depending a state of the fourth NMOS transistor N24 and the second flash memory cell M22. At this time, the fourth NMOS transistor N24 is driven by the output signal of the second inverter I22 for inverting the drain potential of the second flash memory cell M22, that is the potential of the fourth node Q24. The second flash memory cell M22 is a weakly-programmed cell. The supply voltage Vcc is applied to the gate terminal of the second flash memory cell M22. As the gate terminal of the second flash memory cell M22 is connected to the power supply terminal Vcc, the second current Ib through the second flash memory cell M22 is varied depending on the supply voltage Vcc. Therefore, the potential INb of the second node Q22 accordingly changes. In other words, as the supply voltage Vcc is increased, the second current Ib is accordingly increased. Therefore, the potential Inb of the second node Q22 is decreased. On the contrary, as the supply voltage Vcc is decreased, the second current Ib is accordingly decreased. Therefore, the potential INb of the second node Q22 is increased. In other words, as shown in FIG. 3A, the supply voltage Vcc is decreased to decease the second current Ib. If the amount of the second current Ib is smaller than that of the first current Ia, the potential INa of the first node Q21 is lower than the potential INb of the second node Q22, as shown in FIG. 3B. Due to this, the comparator 21 outputs the output signal LVCC of a HIGH state.

The detect point of the power supply voltage may be changed to a desired value by controlling the threshold voltages of the first and second flash memory cells M21 and M22. In addition, it may not be affected by change in the temperature or process, by constructing the circuit symmetrically to which the first and second flash memory cells M21 and M22 connected.

FIG. 4 is a graph showing a simulation result of the low voltage detector according to the present invention, which is a graph showing change in the low voltage detect point when the low voltage detector is driven at the temperature of −40° C. and 25° C., and 90° C. From the drawing, it can be seen that the maximum change of the low voltage detect point is below 0.1V even though both changes in the temperature or process are considered.

As mentioned above, according to the present invention, a low voltage is detected by sensing the difference in current between an over-erased flash memory cell and a weakly-programmed flash memory cell. Therefore, the present invention has an advantage that a low voltage detect point can be changed without modifying a circuit. Further, the low voltage detector of the present invention is not affected by change in the operating power using the over-erased flash memory cell. As a circuit to which the first and second flash memory cells are connected is symmetrically constructed, the circuit is not affected by change in the temperature or process.

The present invention has been described with reference to a particular embodiment in connection with a particular application. Those having ordinary skill in the art and access to the teachings of the present invention will recognize additional modifications and applications within the scope thereof.

It is therefore intended by the appended claims to cover any and all such applications, modifications, and embodiments within the scope of the present invention.

What is claimed is:

1. A low voltage detector, comprising:
a first flash memory cell driven by a ground voltage, for maintaining the potential of a first node to a given potential;
a second flash memory cell driven by a power supply voltage, for controlling the potential of a second node; and
a comparator for comparing the potentials of the first node and the second node.

2. The low voltage detector as claimed in claim 1, wherein said first flash memory cell is an over-erased cell.

3. The low voltage detector as claimed in claim 1, wherein said second flash memory cell is a programmed cell.

4. The low voltage detector as claimed in claim 1, further comprising:
a first load for supplying the power supply voltage to the first node; and
a first switching means for controlling the potential of the first node depending on the potential of a drain terminal of the first flash memory cell.

5. The low voltage detector as claimed in claim 4, wherein said switching means includes:
a first inverting means for inverting the potential of a drain terminal of the first flash memory cell; and
a first NMOS transistor driven depending on an output of the first inverting means.

6. The low voltage detector as claimed in claim 1, further comprising:
a second load for supplying the power supply voltage to the second node; and
a second switching means for controlling the potential of the second node depending on a drain terminal of the second flash memory cell.

7. The low voltage detector as claimed in claim 6, wherein said second switching means includes:
a second inverting means for inverting the potential of the drain terminal of the second flash memory cell; and
a second NMOS transistor driven depending on an output of the second inverting means.
